(19) United States
(12) Patent Application Publication
(10) Pub. No.: US 2026/0072106 A1
(43) Pub. Date: Mar. 12, 2026

(54) Adjusting a Primary Magnetic Field in a Magnetic Resonance System

(71) Applicant: Quantum Valley Investment Fund LP, Waterloo (CA)

(72) Inventors: Donald Edward Carkner, Waterloo (CA); Derek Blair Poirier Thompson, Waterloo (CA); Troy W. Borneman, Waterloo (CA); Hamidreza Mohebbi, Waterloo (CA)

(73) Assignee: Quantum Valley Investment Fund LP, Waterloo (CA)

(21) Appl. No.: 19/386,511

(22) Filed: Nov. 12, 2025

Related U.S. Application Data
(63) Continuation of application No. PCT/CA2024/050678, filed on May 21, 2024.
(60) Provisional application No. 63/504,138, filed on May 24, 2023.

(51) Int. Cl. G01R 33/34; G01R 33/38; G01R 33/3815; G01R 33/383

(52) U.S. Cl. CPC G01R 33/34007; G01R 33/3802; G01R 33/3815; G01R 33/383

(57) ABSTRACT

In a general aspect, a primary magnetic field is adjusted in a magnetic resonance system. In some aspects, a magnetic resonance system includes a primary magnet configured to generate a primary magnetic field; a resonator that defines a sample region in the primary magnetic field; and a support assembly that supports the primary magnet. The support assembly includes a plurality of actuators configured to adjust the sample region in the primary magnetic field by moving the primary magnet relative to the resonator. The plurality of actuators are configured to adjust the sample region in at least five spatial degrees of freedom (e.g., position, orientation, or both).

### CROSS-REFERENCE TO RELATED APPLICATIONS

This application claims priority to U.S. Provisional Ser. No. 63/504,138, filed May 24, 2023, entitled “Adjusting a Primary Magnetic Field in a Magnetic Resonance System.” The above-referenced priority document is incorporated herein by reference in its entirety.

### BACKGROUND

The following description relates to adjusting a location and an orientation of a primary magnetic field in a magnetic resonance system.

Magnetic resonance systems are used to study various types of samples and phenomena. In some magnetic resonance applications, the spins in a sample are polarized by a primary magnetic field, and a resonator manipulates the spins by producing a drive magnetic field at a frequency near the spins'resonance frequencies. Applications of magnetic resonance include, for example, electron paramagnetic resonance (EPR), nuclear magnetic resonance (NMR), magnetic resonance imaging (MRI) and others.

### DESCRIPTION OF DRAWINGS

FIG. 1 is a schematic diagram showing aspects of an example magnetic resonance system.

FIGS. 2A-2B are side-view schematic diagrams showing aspects of an example magnetic resonance system.

FIGS. 3A-3L are perspective-view schematic diagrams showing aspects of a magnet assembly of an example magnetic resonance system.

FIGS. 4A-4C are side-view and perspective view schematic diagrams showing aspects of an example magnetic resonance system.

FIG. 5 is a flow chart showing aspects of an example process for operating a magnetic resonance system.

### DETAILED DESCRIPTION

In some aspects of what is described here, a magnetic resonance system includes actuators that allow the primary magnetic field (its location, orientation, or both) to be adjusted in multiple spatial degrees of freedom. For example, the actuators may allow the primary magnetic field to be translated independently (to adjust location) in multiple spatial degrees of freedom and rotated independently (to adjust orientation) in multiple spatial degrees of freedom.

In some implementations, a magnetic resonance system includes a primary magnet, a resonator, and a support assembly that supports the primary magnet. The primary magnet can generate a primary magnetic field that polarizes a spin ensemble in a sample; and the resonator device can generate a drive magnetic field that manipulates the spins. The primary magnet may have a small size and light weight, for instance, so that the magnetic resonance system can be mobile, light weight, have a low footprint, or a combination of these properties. In some implementations, the support assembly can be used to adjust the position and orientation of the primary magnetic field relative to the sample region.

In some implementations, the support assembly can provide a number of advantages. For example, the support assembly may allow the use of a small primary magnet; the support assembly may securely support the primary magnet in the magnetic resonance system and allow removal of the primary magnet from the magnetic resonance system for maintenance and for easy access to components behind or enclosed by the primary magnet (e.g., the resonator or control circuits enclosed in a cryostat). The support assembly may allow the primary magnetic field to be adjusted (e.g., adjusted in space relative to the sample region) in multiple degrees of freedom for precise alignment of the homogenous region of the primary magnetic field and the drive magnetic field (e.g., maximally perpendicular to each other).

Aspects of the systems and techniques described here can be adapted for various types of magnetic resonance systems. For example, computer systems, programmable controllers and other hardware components can be adapted for a nuclear magnetic resonance (“NMR”) system, an electron paramagnetic resonance (“EPR”) system, or another type of magnetic resonance system. As another example, systems and techniques described here may be deployed in a magnetic resonance system that includes a probe in a probe-less magnetic resonance system. In some cases, the magnetic resonance system can be adapted to operate with liquid samples, solid samples, liquid crystal samples, spin-labeled protein samples, biological samples (e.g., blood samples, urine samples, saliva samples, etc.), or other types of samples to be measured or otherwise analyzed by a magnetic resonance system. As another example, a magnetic resonance system may include components that operate in a cryogenic environment (e.g., at 77 K, 4 K, or other cryogenic temperatures below 273 K), or a magnetic resonance system may operate at non-cryogenic temperatures including room temperatures.

In some cases, the systems and techniques described here can be compatible with multiple different types of resonators, cryogenic systems, probe configurations and other components in a variety of magnetic resonance systems. For example, the systems and techniques can be designed for compatibility with non-superconducting resonators and superconducting resonators fabricated from a variety of superconducting materials. The resonator can be, for example, a microstrip, an array of microstrips, a cavity, a coil, a coplanar waveguide (CPW), another type of resonator for magnetic resonance systems. Additionally, the resonator could be, for example, a rectangular cavity resonator, a cylindrical cavity resonator, a dielectric resonator, a loop gap resonator, or any lumped element resonator. In some cases, the systems and techniques presented here can be deployed in connection with various cryogenic systems, including, for example, compact closed-cycle systems, open-cycle, liquid cryogen systems and others. In some cases, the systems and techniques presented here can be deployed in connection with various probes, including compact probe designs that may enable low-noise cryogenic receiver amplifiers to be used in a variety of configurations without disturbing sample changing methods. In some cases, a combination of these and potentially other advantages and improvements may be obtained.

In some cases, the techniques and system described here can be deployed in connection with continuous wave (CW) magnetic resonance (e.g., using CW ESR spectroscopy or CW NMR spectroscopy methodology), pulse magnetic resonance (e.g., using pulsed ESR spectroscopy or pulsed NMR spectroscopy methodology), or a combination of these and other MR regimes. In a typical continuous wave (CW) spectroscopy experiment, the resonator applies a low-power, continuous excitation field (e.g., a radio frequency or microwave frequency drive field) to the sample over a time period that is relatively long (e.g., relative to characteristic relaxation times) in order to bring the spin ensemble to a steady state. The resonance frequencies of the spins are swept over a range (by sweeping the principal magnetic field), and the resulting absorption or reflection spectrum is measured. In a typical pulsed spectroscopy experiment, the resonator applies a sequence of intense, high-power pulses of radiation (e.g., radio frequency or microwave pulses) to the sample, while the principal magnetic field is held constant. The resulting state of the spins can then be observed, for example, by acquiring a free induction decay (FID) or spin echo, which can then be Fourier transformed to obtain a spectrum.

Aspects of the systems and techniques described here can be adapted for various types of applications. For example, the systems and techniques described here may be used for structural biology measurements, for instance, to measure structural properties of proteins or protein complexes in a biological sample (e.g., a blood sample, a urine sample, a saliva sample, a sweat sample, or another type of biological sample). Such measurements can be useful in clinical applications, for example, diagnostics, treatments, pharmaceutical drug discovery/development and understanding the structure and function of membrane proteins, and other applications.

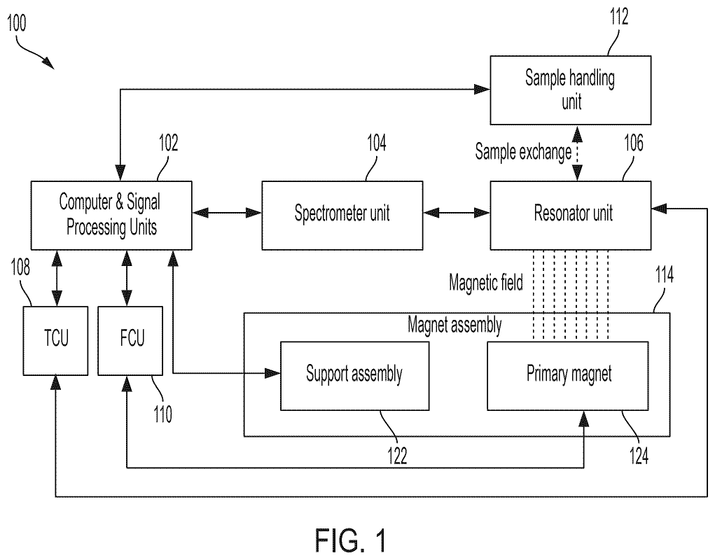

FIG. 1 is a schematic diagram showing aspects of an example magnetic resonance system 100. Generally, the example magnetic resonance system 100 can be an EPR system, an NMR system, or another type of magnetic resonance system. The example magnetic resonance system 100 includes computer and signal processing units 102, a spectrometer 104, a resonator unit 106, a temperature control unit (TCU) 108, a field control unit (FCU) 110, a sample handling unit 112, and a magnet assembly 114. In some examples, each of the units of the magnetic resonance system 100 may include an associated electronic circuit and other components, including housing, ports, etc.

In some cases, the computer and signal processing units 102 communicate with the spectrometer 104, the TCU 108, the FCU 110, the sampling assembly 112, the magnet assembly 114, and other units/components of the magnetic resonance system 100. In some instances, the computer and signal processing units 102 can be implemented as a single computer device (e.g., a laptop computer, a workstation, a desktop computer, a server) or by multiple computer devices. In some cases, the computer and signal processing units 102 can be co-located with the spectrometer 104, the resonator unit 106, and the other units or components of the example magnetic resonance system 100; and may be directly connected to other units and components of the magnetic resonance system 100, for example, by cables (e.g., coaxial cables, network cables, waveguides, etc.) or other types of local communication channels. In some cases, all or part of the computer and signal processing units 102 is located remotely from the spectrometer 106, and resonator unit 106, and may be directly connected to the units and components of the magnetic resonance system 100, for example, by a network (e.g., the Internet, a virtual private network, a wide area network, etc.) or other types of remote communication channels. Some aspects of the computer and signal processing units 102 may be deployed in a cloud computing environment, or otherwise. In some implementations, the computer and signal processing units 102 include one or more user interfaces such as, for example, a touchscreen, a pointing device, a keyboard, a microphone, etc., that allow a user to interact with and provide input to the computer and signal processing units 102 of the magnetic resonance system 100. In some implementations, the computer and signal processing units 102 include one or more output devices that allow the computer and signal processing units 102 to present information and data (e.g., graphical user interfaces, etc.) for display to a user.

The computer and signal processing units 102 can include, for example, a central processor unit (CPU) or another type of general-purpose processor that runs software. The computer and signal processing units 102 can include, for example, a graphics processing unit (GPU), a cryptographic processor unit, a field-programmable gate array (FPGA) unit, a digital signal processing (DSP) unit, or another type of data processing apparatus. In some instances, the computer and signal processing units 102 may be configured to perform digital signal processing and signal averaging. In particular, the computer and signal processing units 102 may be configured to identify a pulse sequence for a magnetic resonance experiment; generate sets of digital intermediate frequency (IF) signal information by modulating respective pulses in the pulse sequence at an intermediate frequency; generate a hardware control sequence based on the pulse sequence; convert the digital IF signal information and the hardware control sequence to the signal processing unit 104; generate digitized magnetic resonance detection signal; demodulate the digitized magnetic resonance detection signal at the intermediate frequency for phase-sensitive detection; and display data. In some instances, the computer and signal processing units 102 may be configured to perform other operations. For example, the computer and signal processing units 102 may be configured to generate multiple resonance pulses by modulating pulses in a pulse sequence at different intermediate frequencies and superposing the modulated pulses, for example, for performing a multiple magnetic resonance measurement. In this case, the computer and signal processing units 102 may be also configured to demodulate the digitized magnetic resonance detection signal at the multiple intermediate frequencies. In some instances, the computer and signal processing units 102 may be controlled by software to execute a pre-configured program stored in a memory unit of the computer and signal processing units 102.

The computer and signal processing units 102 may be configured to generate analog IF electrical signals based on the digital IF signal values according to the hardware control sequence; and to transmit the analog IF electrical signals to the resonator unit 106 via the spectrometer 104. The computer and signal processing units 102 can further receive a magnetic resonance detection signal from the resonator unit 106 via the spectrometer 104. The magnetic resonance detection signal includes a signal with amplitude, phase, and frequency modulation at an intermediate frequency and can be digitized by operation of the computer and signal processing units 102. The digitized magnetic resonance detection signal (e.g., spin signals) can be demodulated for further processing (e.g., for measurement, pulse transient control and correction, etc.) by operation of the computer and signal processing units 102. In some implementations, the computer and signal processing units 102 may be implemented as the computer and signal processing units 606 of the example magnetic resonance system 600 in FIGS. 6A-6C or in another manner. In some instances, the computer and signal processing units 102 may be configured to perform other operations.

In some instances, the spectrometer 104 includes microwave or radio frequency hardware components (e.g., switches, mixers, amplifiers, attenuators, etc.) that generate and receive microwave or radio frequency signals. For instance, the spectrometer 104 may be configured to process single sideband X-band (8-12 GHz), Ku-band signals (12-18 GHz), Q-band signals (33-50 GHz), W-band signals (75-110 GHz, or signals in other microwave frequency bands. In some examples, the spectrometer 104 may include a low phase noise microwave synthesizer to generate system master oscillator signals and analog spectrometer local oscillator signals, an IQ mixer device to upconvert analog IF electrical signals to a single sideband signal that can be applied to the resonator unit 106 and to provide local oscillator suppression and image suppression, and a bandpass filter device to suppress noise outside spectrometer bandwidth on a transmitter side. In some instances, the spectrometer 104 may include other circuit components. In some implementations, the spectrometer 104 can receive the analog IF electrical signals from the computer and signal processing units 102 and output a magnetic resonance control signal (e.g., upconverted and single band analog IF electrical signals). In some implementations, the magnetic resonance control signal has a frequency in a radio frequency or microwave regime. In the example shown in FIG. 1, the magnetic resonance control signal from the spectrometer 104 is passed to the resonator unit 106.

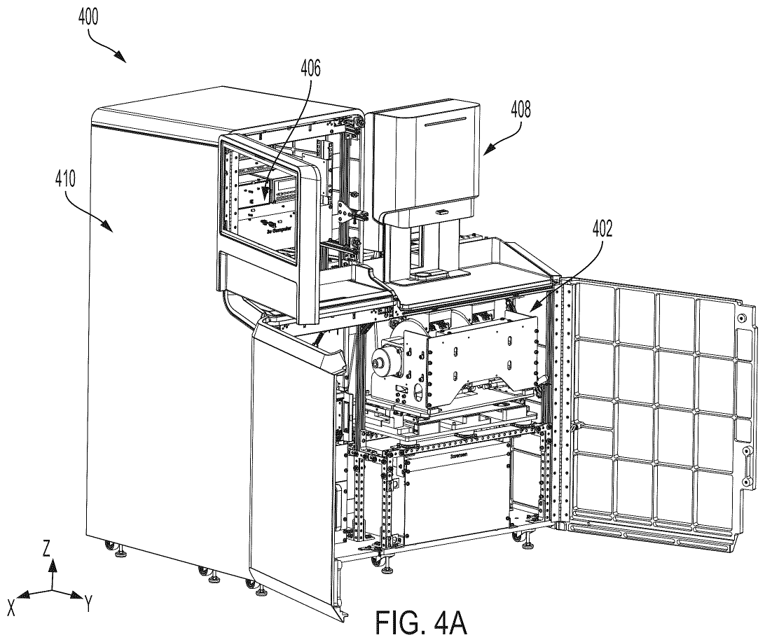

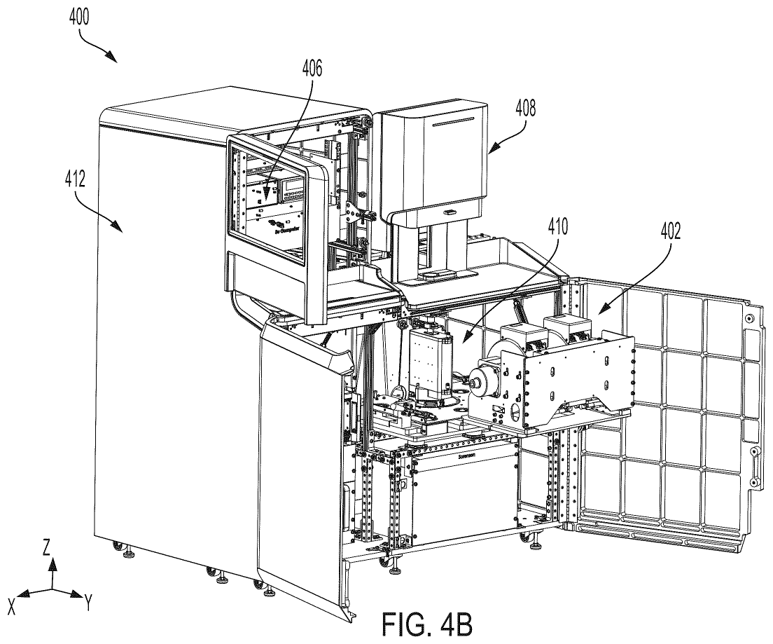

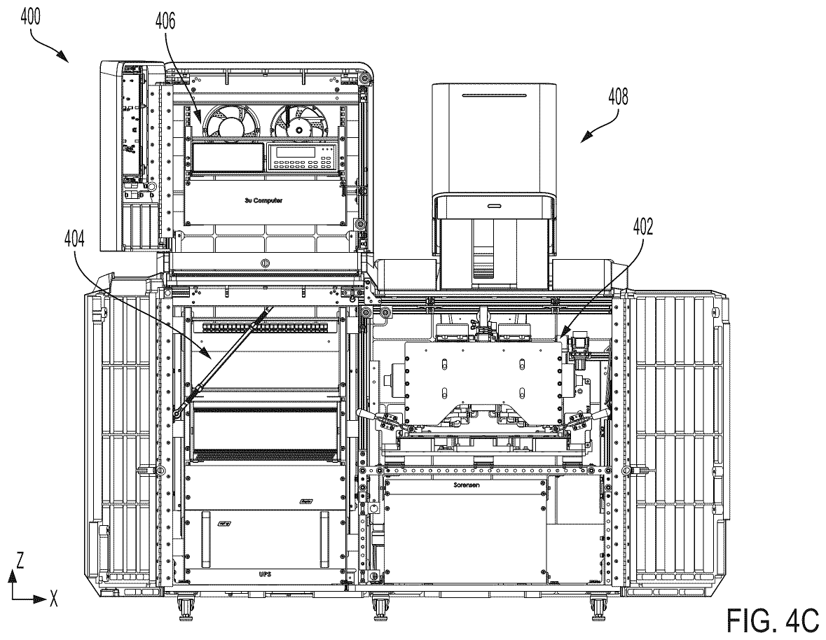

In some instances, the spectrometer 104 can be digitally controlled by the digital control signals from the computer and signal processing units 102. In some instances, the spectrometer 104 may include one or more switch devices and amplifier devices. In some implementations, at least a portion of the spectrometer 104 operates in an elevated temperature, e.g., room temperature, outside of a cryogenic environment. In some instances, some components of the spectrometer 104 may operate at a cryogenic environment, for example, the same or different cryogenic environment where the resonator unit 106 resides. In some examples, the spectrometer 104 may be digitally controlled to perform fast switching between pulses and continuous-wave modes of operation. In some implementations, the spectrometer 104 may be implemented as the spectrometer 404 of the example magnetic resonance system 400 in FIGS. 4A-4C or in another manner. In some instances, the spectrometer 104 may include other components or may be configured to perform other operations.

In some instances, the spectrometer 104 may include an amplifier device (e.g., a cryogenic LNA device). In some implementations, the spectrometer 104 can include a mixer device for down-converting magnetic resonance detection signals received from the resonator device 106 to an intermediate frequency (f_{IF}), by mixing the magnetic resonance detection signals with a local oscillator frequency (f_{LO}). The spectrometer 104 may also include a filter device that removes unwanted frequency components, for example, a bandpass IF filter device that rejects frequencies near a frequency value of f_{LO}-f_{IF} from the mixer device and suppresses noise outside the receiver bandwidth (±f_{IF}). The spectrometer 104 may also include other components such as, for example, an IF amplifier device, a lowpass filter device, and other circuit components. In some instances, the spectrometer 104 may include various stages of filtering and amplification to reduce noise bandwidth. The spectrometer 104 shown in FIG. 1 can accept both low-level spin signal inputs and high-level pulse transient digitizing inputs. In some examples, the spectrometer 104 may be controlled to switch between modes of operation, for example, between a magnetic resonance measurement mode and a pulse transient digitizing/correcting mode.

In some instances, the spectrometer 104 may be configured to process single-sideband X-band signals (8-12 GHz), Ku-band signals (12-18 GHz), Q-band signals (33-50 GHz), W-band signals (75-110 GHz), or signals in other microwave frequency bands. For example, the spectrometer 104 may include a single stage of up-conversion or down-conversion with a single microwave synthesizer device that is configured to generate LO signal at a respective microwave frequency band. For another example, the spectrometer 104 may include two or more stages of up-conversion or down-conversion with two or more microwave synthesizer devices and two or more corresponding mixer devices.

In the example shown in FIG. 1, components of the spectrometer 104 are electromagnetically coupled to (e.g., by coaxial cables, waveguides, etc.), and adapted to communicate with the resonator unit 106. For example, the spectrometer 104 can be adapted to provide a voltage or current electrical signal that drives the resonator unit 106. In the example shown in FIG. 1, the spectrometer 104 can also acquire magnetic resonance data based on control signals delivered to the resonator device 106. For example, the spectrometer 104 may receive magnetic resonance detection signals generated by an interaction between the resonator unit 106 and samples contained in the resonator unit 106 based on the magnetic resonance control signals received at the resonator unit 106.

In some implementations, the magnetic resonance system 100 includes a superheterodyne spectrometer system. Generally, a superheterodyne spectrometer generates magnetic resonance control signals by mixing intermediate frequency (IF) signals with local oscillator (LO) signals to produce a high frequency (e.g., RF or microwave) signal that can then be further processed and passed on to the resonator unit 106; a superheterodyne spectrometer processes high-frequency magnetic resonance detection signals (e.g., spin signals) from the resonator unit 106 by mixing the high-frequency signals with LO signals to produce an IF signal, which can then be further processed and digitized for analysis by the data processing apparatus 102.

Superheterodyne operation can allow for increased sensitivity, selectivity, and signal-to-noise ratio, among other advantages. By generating control information and processing detected signals at IF frequencies, superior control and data processing can be achieved in some cases. Also, by using one or more tunable local oscillators, the superheterodyne spectrometer can tune to multiple distinct spin resonance frequencies, making it a versatile system.

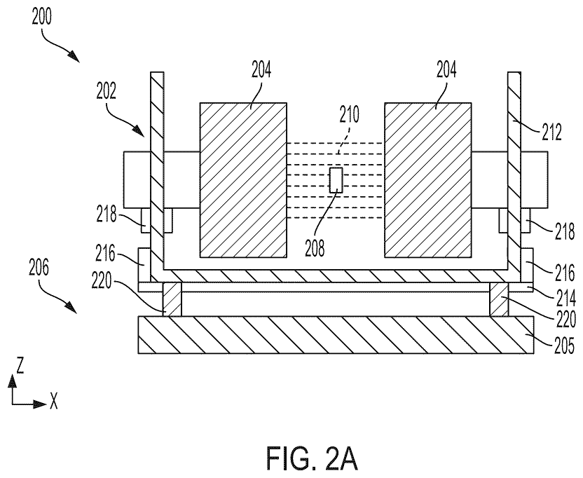

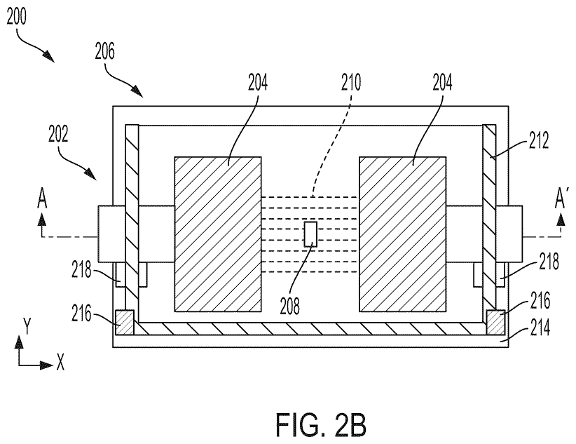

In some implementations, the resonator unit 106 resides in a cryogenic environment (e.g., at 77 K, 4 K, or other cryogenic temperatures below 273 K), for example, in a cryostat. The resonator unit 106 includes a resonator that generates electromagnetic fields (e.g., drive magnetic fields) in a sample region of the magnetic resonance system defined by the resonator according to the control signals received at the resonator. The resonator unit 106 may include signal wirings for communicating microwave signals and digital control signals, cryogenic receiver components, and internal hardware for temperature setting and stabilization. In some instances, the computer and signal processing units 102 may also communicate control signals to the resonator unit 106. In some instances, the resonator can be, for example, a non-superconducting resonator, a superconducting resonator, a microstrip, an array of microstrips, a coplanar waveguide (CPW), a cavity, a coil, a waveguide, a rectangular cavity resonator, a cylindrical cavity resonator, a dielectric resonator, a loop gap resonator, or another type of resonator. Additionally, the resonator could be, for example, a rectangular cavity resonator, a cylindrical cavity resonator, a dielectric resonator, a loop gap resonator, or any lumped element resonator. In some instances, the resonator of the resonator unit 106 may be implemented as the resonator unit 208 in FIGS. 2A-2B or in another manner.

In some implementations, the TCU 108 is configured and operated to monitor and stabilize the temperature of the cryogenic environment where the resonator unit 106 resides. In some examples, the example magnetic resonance system 100 includes other circuits or components. For example, the TCU 108 may measure and stabilize temperatures of various components using closed loop feedback control. In some instances, the example magnetic resonance system 100 includes a cryostat cooled by liquid Helium or liquid Nitrogen which can be maintained at a cryogenic environment (e.g., at 77 K, 4 K, or other cryogenic temperatures below 273 K). In certain examples, a cryostat of the example magnetic resonance system 100 includes liquid cryogen-free system, e.g., dry cryostats. In some instances, a cryostat of the example magnetic resonance system 100 includes internal control hardware for temperature setting and stabilization.

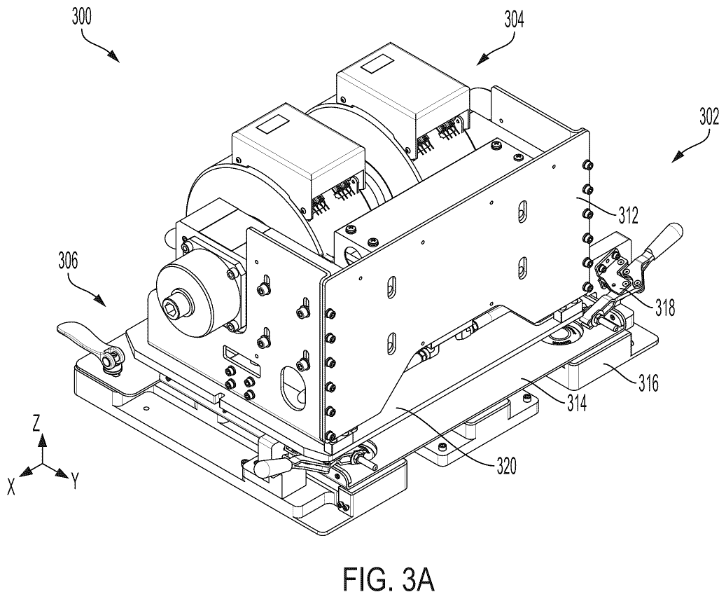

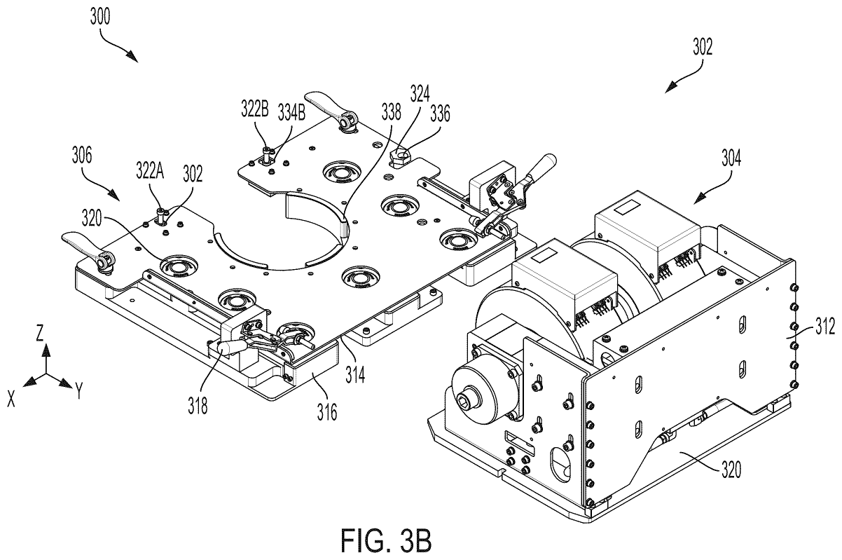

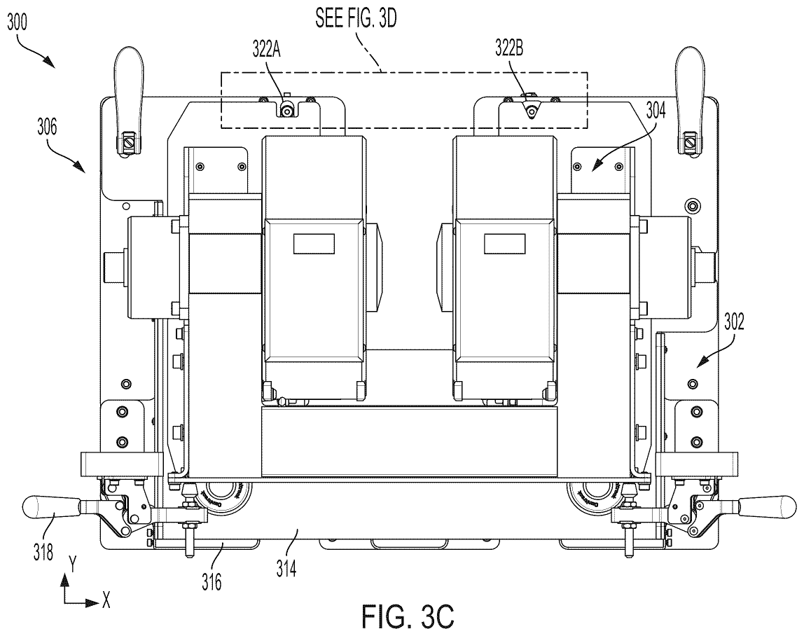

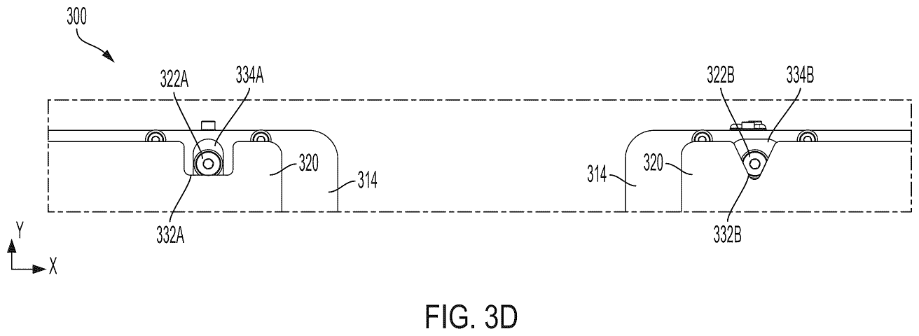

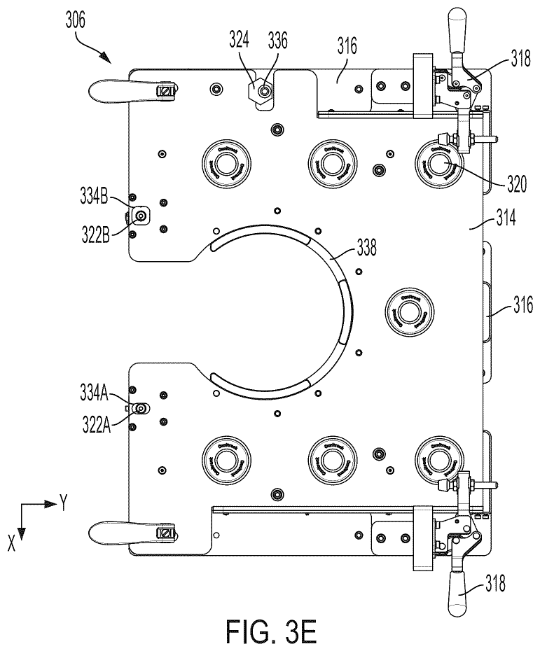

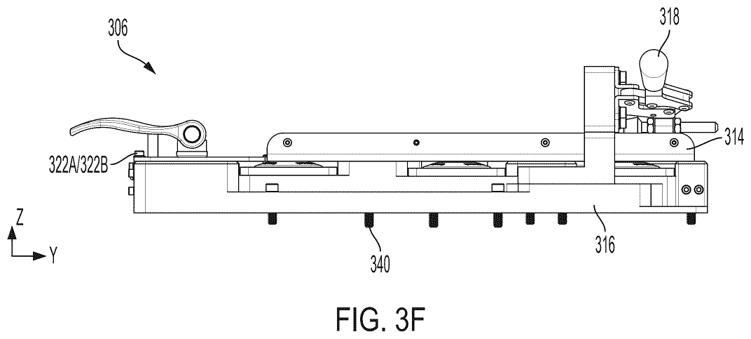

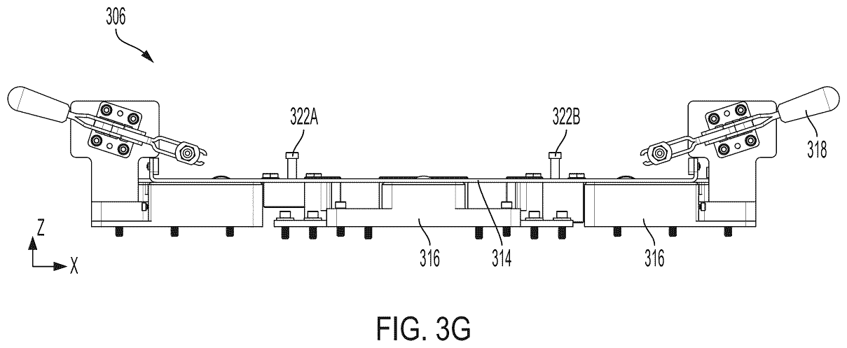

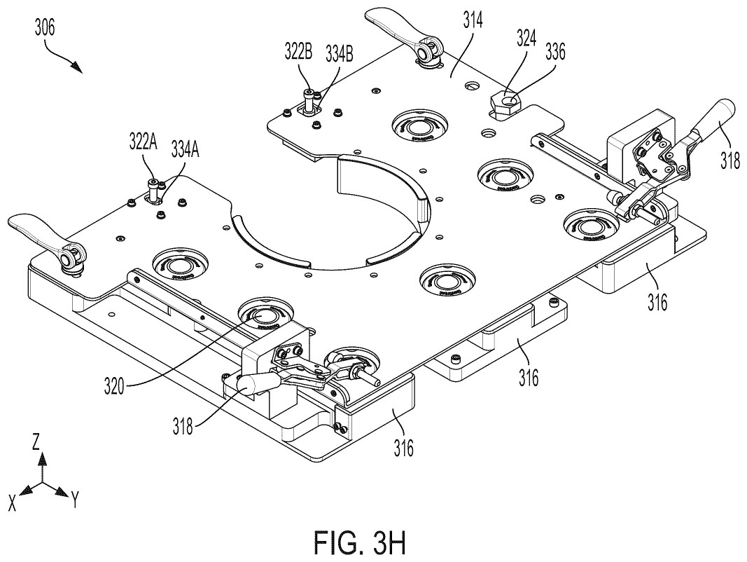

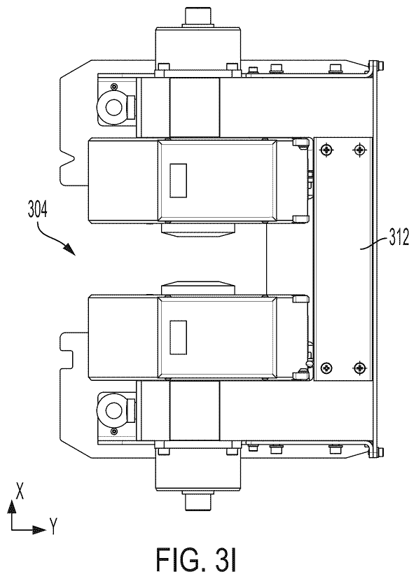

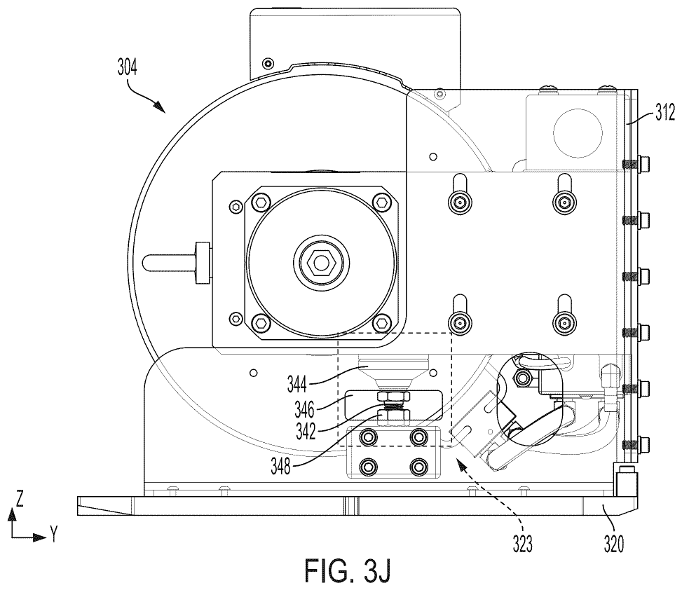

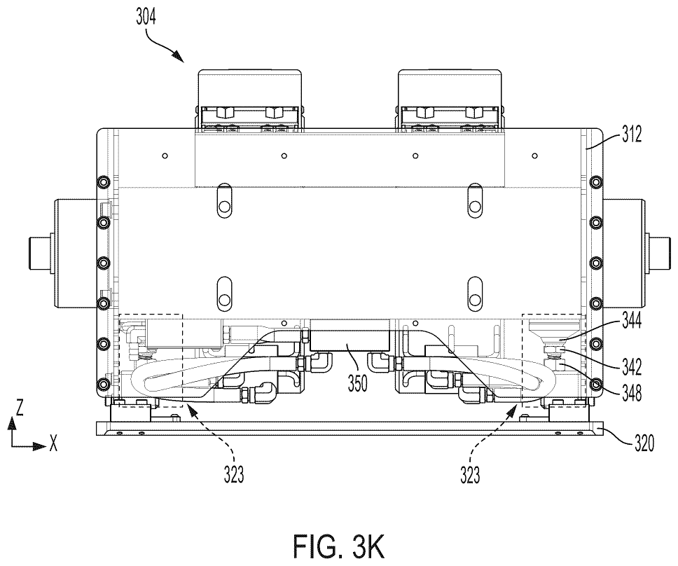

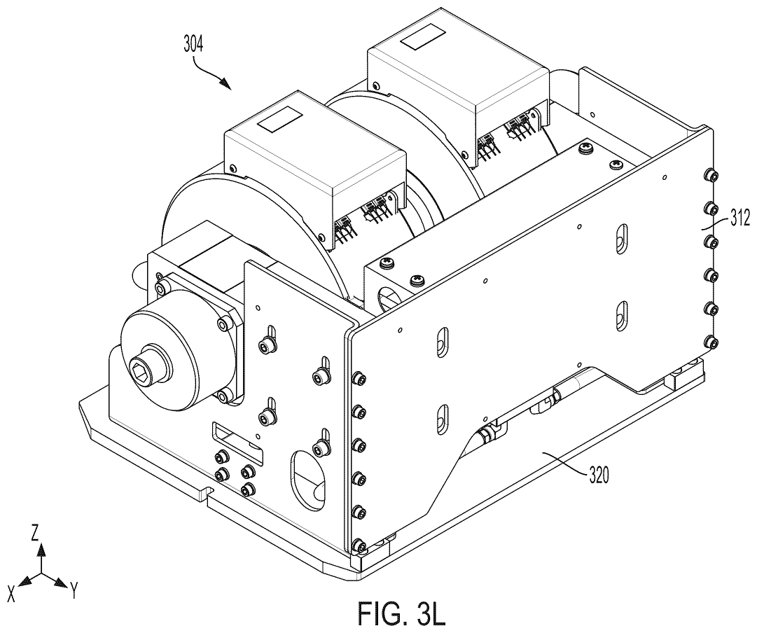

In some instances, the FCU 110 can be configured and operated to monitor, stabilize, and vary a primary magnetic field in the magnetic resonance system. The primary magnetic field is the external B₀ field (the quantizing field) that is applied to the sample region and is generated by a primary magnet 124, which can be implemented as an electromagnet, a permanent magnet, a superconducting magnet, or another type of magnet. For example, the FCU 110 may measure and stabilize a quantizing magnetic field using closed loop feedback control. The FCU 110 of the magnetic resonance system 100 may include a magnet configured to generate magnetic fields corresponding to X-band spin resonance (e.g., a field strength in the range of approximately 0-4000 G). In some implementations, the FCU 110 further includes a Hall probe which interfaces with the computer and signal processing units 102 to receive control signals from the computer and signal processing units 102 and apply appropriate current to the primary magnet 124. In some implementations, the primary magnet 124 may be implemented as the primary magnet 204 in FIGS. 2A-2B, 328 in FIGS. 3D-3E, or in another manner.

In some implementations, the magnet assembly 114 is configured to adjust a primary magnetic field in the magnetic resonance system 100 relative to the sample region defined by the resonator unit 106. As shown in FIG. 1, the magnet assembly 114 includes a support assembly 122 and the primary magnet 124. In some aspects of operation, the primary magnet 124 of the magnet assembly 114 in the magnetic resonance system 100 generates a primary magnetic field in a controlled environment of a sample region defined by the resonator unit 106. In some implementations, the primary magnet 124 includes an electromagnet or another type of system that can be controlled by the FCU 110 by tuning the current from an electromagnet power supply. In some instances, the primary magnet 124 may include a gradient system that generates one or more gradient fields that spatially vary over the sample region. Generally, the primary magnetic field generated by the primary magnet 124 quantizes the spin states and sets the Larmor frequency of the spin ensemble.

In some implementations, the support assembly 122 of the magnet assembly 114 is configured to securely hold the primary magnet 124 and adjust (e.g., modify according to specified adjustments) the spatial position and orientation of the primary magnetic field relative to the sample region. In particular, the support assembly 122 is configured to translate the spatial position and rotate the spatial orientation of the primary magnet 124 relative to the resonator unit 106. In some instances, tuning the spatial position and orientation of the primary magnet 124 relative to the resonator unit 106 can be performed by executing an alignment calibration process. In some instances, the support assembly 122 includes a mounting frame where the primary magnet 124 is securely mounted, a stage assembly where the mounting frame can be positioned and supported, and actuators that can be configured to adjust a location of the sample region in the primary magnetic field by moving the primary magnet 124 relative to the resonator unit 106. In some instances, the actuators can be manually adjusted, electronically controlled through the computer and signal processing units 102, or controlled in another manner. In some implementations, the mounting frame of the support assembly 122 holds the primary magnet 124; and is removable from the stage assembly, e.g., via roller balls or another mechanism. In some instances, the mounting assembly may be implemented as the support assembly 202, 302 in FIGS. 2A-2B and 3A-3B, or in another manner.

In some aspects of operation, a spin ensemble in the sample interacts with the resonator unit 106. Control of spins in the sample can be achieved, for example, by a radio frequency or microwave magnetic field generated by the resonator unit 106. The drive frequency can be tuned to the spins'resonance frequency, which is determined by the strength of the primary magnetic field and the gyromagnetic ratio of the spins. The spins can be a collection of particles having non-zero spin that interact magnetically with the applied fields. For example, the spin ensemble can include nuclear spins, electron spins, or a combination of nuclear and electron spins. Examples of nuclear spins include hydrogen nuclei (1H), carbon-13 nuclei (13C), and others. In some implementations, the spin ensemble is a collection of identical spin − 1/2 free electron spins attached to an ensemble of large molecules.

In some implementations, the sample handing unit 112 includes a sample transfer device configured to move a sample holder and position the sample holder relative to a resonator unit 106 in the primary magnetic field of the generated by the primary magnet 124 of the magnetic resonance system. In some instances, the sample transfer device may be driven by an actuator system. The actuator system may be a single-degree-of-freedom linear actuator that translates the sample transfer device in a linear fashion along an axis of the sample transfer device. The actuator system may be a multi-degree-of-freedom actuator that moves the sample transfer device in a linear fashion along two independent (e.g., perpendicular) axes. In certain instances, the actuator system may be coupled to the computer and signal processing units 102 that controls operation of the actuator system.

FIGS. 2A-2B are side-view and top-view schematic diagrams showing aspects of a magnet assembly 200 of an example magnetic resonance system. As shown in FIGS. 2A-2B, the example magnet assembly 200 includes a support assembly 202 and a primary magnet 204. In some implementations, the support assembly 202 is operated to adjust the position and orientation of the primary magnet 204 relative to a sample region 208 defined by a resonator unit (e.g., the resonator unit 106 of FIG. 1 or another type of resonator unit). In some examples, the magnet assembly 200 may include additional or different components, and the components may be arranged as shown or in another manner. For example, the magnet assembly 200 may include electrical circuit, communication interfaces, and control components for receiving current from an external computer and signal processing units (e.g., the external computer and signal processing units 102 of the magnetic resonance system 100 in FIG. 1) In the example shown, the primary magnet 204 is configured to generate a primary magnetic field 210 in the sample region 208, where a magnetic resonance sample is located during operation. The primary magnetic field 210 produced by the primary magnet 204 is configured to polarize spins in the sample region 208. A drive magnetic field produced by the resonator unit can also be applied to the magnetic resonance sample in the sample region 208, to manipulate the spins in the sample region 208. In some instances, the primary magnet 204 may be a permanent magnet, an electromagnet, a superconducting magnet, a hybrid magnet, or another type of magnet. In some instances, the primary magnet 204 may be communicably connected to power supply or control electronics of the magnet assembly 200.

As shown in FIGS. 2A-2B, the support assembly 202 includes a mounting frame 212 configured to securely hold the primary magnet 204 and a stage assembly 206 configured to serve as a foundation on which the mounting frame 212 rests. The stage assembly 206 includes a plate 214, locking clamps 216, and a base 205. The mounting frame 212 is securely integrated on the plate 214, contacting the mounting frame 214 by engaging the locking clamps 216 on the plate 214. The base 205 supports the plate 214. In some instances, the stage assembly 206 may include one or more alignment posts for alignment of the mounting frame 212 when being positioned on the plate 214.

In some implementations, the support assembly 202 includes multiple actuators 218, 220 that are configured to adjust the sample region 208 in the primary magnetic field 210 by moving the primary magnet 204 relative to the resonator unit. The multiple actuators 218, 220 can be operated to adjust the sample region 208 in the primary magnetic field 210 in five spatial degrees of freedom, which include three linear degrees of freedom and two rotational degrees of freedom. In particular, the plate 214 of the stage assembly 206 includes actuators 220 that can translate the mounting frame 212 and thereby translate the primary magnet 204 on the mounting frame 212 along the X and/or Y directions relative to the base 205. As shown in FIG. 2B, the X and Y directions are mutually orthogonal spatial directions. In some implementations, the plate 214 further includes actuators 220 that can be operated to rotate the mounting frame 212 and thereby rotate the primary magnet 204 on the mounting frame 212 about the Z direction. As shown in FIG. 2A, the Z direction is orthogonal to the X and Y directions (thus, the X, Y and Z directions are mutually orthogonal). In some implementations, the mounting frame 212 includes actuators 218 which are configured to translate the primary magnet 204 along the Z direction relative to the mounting frame 212. In some instances, the actuators 218 on the mounting frame 212 can be operated to rotate the primary magnet 204 about the Y direction, for example, by fixing one actuator 218 on one end of the mounting frame 212 while tuning the other actuator 218 on the opposite end of the mounting frame 212 or adjusting the two actuators 218 along opposite directions. The actuators 218, 220 of the support assembly 202 allow independent adjustment of the position and orientation of the primary magnet 204 in three mutually orthogonal directions (e.g., X, Y, and Z directions) and about two rotational axes (e.g., Y and Z directions),

In some instances, the actuators 220 may include two adjustable locating pins, which can be operated to perform linear adjustments along the X-and Y-axes. In this way, the X-Y adjustments can be made independent from the rotation adjustment about the Z axis. For example, one adjustable locating pin moves the primary magnet 204 only in the X direction, and the other one moves the primary magnet 204 in both X and Y directions. In some instances, the actuators 220 may be implemented as the locating pins 322A, 322B, 408A, 408B in FIGS. 3B-3D, 4A-4D, or in another manner. In some examples, rotation around the Z axis can be performed by operating an eccentric cam positioned between the plate 214 and the base 205. In some implementations, the actuators 220 may be implemented as the eccentric cam 324, 410 in FIGS. 3B, 4A, 4D, or in another manner. In some cases, the rotational access is defined by a pivot point centered on the sample region. Once the orientation is properly aligned, the plate 214 can be locked into place with two over-center cams or another mechanism to prevent unwanted rotation.

In some instances, alignment of the primary magnet 204 relative to the sample region 208 can be measured by monitoring characteristics of a spin system of a standard sample in the sample region 208, for example, spectral shape or various decay times. A standard sample that has well-defined, known and reproducible magnetic resonance properties, such as a vial of water or a phantom filled with a specific solution, can be used for performing the alignment process. The standard sample can be placed in the magnetic resonance system at the sample region 208, for example, by operation of the sample handling unit 112 in FIG. 1. The orientation and location of the primary magnet 204 can be adjusted by operating the actuators 218, 220 of the support assembly 204 iteratively to achieve an optimized signal (e.g., a signal that meets predefined criteria).

Once the position and orientation of the primary magnet 204 are determined, the standard sample can be removed, and samples can be placed in the sample region 208 and magnetic resonance data can be acquired (e.g., by applying pulse sequences to the resonator unit). The acquired data can then be used to confirm that the sample region is properly positioned and oriented in the primary magnetic field 210. Once the position and orientation of the primary magnet 204 are determined, it is possible to remove and replace the primary magnet 204 without re-performing the alignment process. The mounting frame 212 can engage with the locating pins, returning the primary magnet 204 to the aligned position with a high degree of precision (e.g., +/−1 mm, 2 mm, 5 mm, or in another range). In some implementations, the support assembly 204 can be operated to reposition the primary magnet 204, for example, when changes are made, or during regular maintenance of the system, etc.

FIGS. 3A-3L are perspective-view and top-view schematic diagrams of a magnet assembly 300 of an example magnetic resonance system. As shown in FIGS. 3A-3D, the example magnet assembly 300 includes a support assembly 302 and a primary magnet 304 configured to generate a primary magnetic field. The support assembly 302 includes a mounting frame 312 and a stage assembly 306. In some examples, the magnet assembly 300 may include additional or different components, and the components may be arranged as shown or in another manner. For example, the magnet assembly 300 may include components of a cooling system to cool the primary magnet 304, e.g., chiller water input/output ports, pipelines, water exchange box, etc.

As shown in FIGS. 3A-3H, the stage assembly 306 includes a plate 314 and locking clamps 318 that secure the mounting frame 312 to the plate 314. As shown in FIGS. 3A-3H, the stage assembly 305 also includes rolling support 320 configured to support the mounting frame 312, for example, when loading the mounting assembly 312 onto the plate 314, unloading the mounting frame 312 from the plate 314, and when adjusting a location of the mounting frame 312 relative to the plate 314. The plate 314 rests on the rolling supports 320; and the rolling supports 320 are fixed on the base 316. The stage assembly 306 further includes locating pins 322A, 322B configured to translate the mounting frame 312 in the X and Y directions so as to adjust the location of the mounting frame 312 on the plate 314, and a cam 324 configured to rotate the mounting frame 312 about an axis of rotation oriented in the Z direction so as to adjust the orientation on the mounting frame on the plate 314. In some implementations, the mounting frame 312 contacts the plate at the locating pins 322A, 322B. In some instances, the plate 314 is configured to provide a reference for the locating pins 322A, 322B; and the reference can rotate around the Z direction. In some instances, the stage assembly 306 may include other components.

As shown in FIGS. 3B and 3D-3H, the plate 314 includes two tracks 334A, 334B associated with the two locating pins 322A, 322B. The tracks 334A, 334B have shapes with dimensions defining respective ranges of movement of the locating pins 322A, 322B. The mounting frame 312 includes a tray 320 which includes two grooves 332A, 332B associated with the two locating pins. During operation, when the mounting frame 312 is secured on the plate 314, the tray 320 is pushed against the locating pins 322A, 322B at the grooves 332A, 332B. Adjusting the position of the locating pin 322A in the track 334A pushes the tray 320 at the groove 332A, and thus, moves the mounting frame 312 relative to the plate 314 in the Y direction. Similarly, adjusting the position of the locating pin 322B in the track 334B pushes the tray 320 at the groove 332B and thus, moves the mounting frame 312 relative to the plate 314 in both X and Y directions. As shown in FIGS. 3C-3D, the groove 332A on the tray 320 has a rectangular shape; and the groove 332B on the tray 320 has a triangular shape. In some instances, the tracks 334A, 334B and grooves 332A, 332B may have other shapes or dimensions; and may reside at other locations in the magnet assembly 300. In some instances, the aligning pins 322A, 322B may be operated manually, or controlled by a linear actuator which can translate rotary motion into linear motion, or in another manner.

As shown in FIGS. 3B, 3E, 3H, the plate 314 of the stage assembly 306 also includes a groove 336 associated with the cam 324. The cam 324 is an eccentric cam with its center of rotation offset from its center of mass, which causes the cam 324 to rotate in a circular motion while also moving in a linear motion, the linear motion of the cam 324 can be used to move the plate 314 around a bearing 338. The bearing 338 may be mounted in a fixed position (e.g., on the base 316). The rotary motion of the plate on the bearing 338 causes rotary motion of the mounting frame 312 relative to the resonator unit about the Z direction. In some instances, the cam 324 may be operated manually, by a motor controlled by the computer and signal processing units 102 in FIG. 1, or in another manner.

As shown in FIGS. 3I-3L, the mounting frame 312 holding the primary magnet 304 is mounted on the tray 320. The primary magnet 304 is attached to the mounting frame 312 using screws or bolts. The primary magnet 304 is also supported by linear actuators 323 for translating the primary magnet 304 along the Z direction and for rotating the primary magnet 304 about the Y direction. Each linear actuator 323 includes a locking nut 348, a threaded support 344 which moves one end of the primary magnet 304, and an adjustment hex nut 342 which is used to adjust the position of the threaded support 344. During operation, the adjustment hex nut 348 can be adjusted which moves the threaded support 344 along the threaded rod, which then moves one end of the primary magnet 304 along the Z direction. In some instances, the linear actuators 323 can be adjusted to cause rotatory motion of the primary magnet 304 about the Y direction.

FIGS. 4A-4C are perspective-view and side-view schematic diagrams showing aspects of an example magnetic resonance system 400. As shown in FIGS. 4A-4C, the example magnetic resonance system 400 is a self-contained unit including a magnet assembly 402, a spectrometer 404, a computer and signal processing units 406, a sample handling unit 408 and a cryostat 410, which are stored in a free-standing cabinet 412.

Front doors of the cabinet 412 can be opened to access respective units and subsystems mounted on racks of the cabinet 412. The magnetic resonance system 400 can be disconnected from building utilities (e.g., electricity, clean dry air, chiller water) and moved to a new location (e.g., between laboratories). The instrument rack on the left supporting the computer and signal processing units 406 and the spectrometer 404 is part of the “all in one unit”, which ensures cables are routed to maximize signal transmission quality to and from the cryostat. Cable damage can be minimized; noise emission can be reduced; and other advantages can be achieved. In some examples, the example magnetic resonance system 400 may include additional or different components, and the components may be arranged as shown or in another manner.

As shown in FIGS. 4A-4C, one of the front doors of the cabinet 412 can be opened to allow a magnet cart to be rolled up, to unload the mounting frame with a primary magnet (e.g., the mounting frame 312 with the primary magnet 304 as shown in FIGS. 3A-3J) from a stage assembly (e.g., the stage assembly 306 in FIGS. 3A-3J) to the cart, and to be transferred outside of the compartment of the cabinet 412 for replacement or other maintenance, for example, when performing maintenance to the cryostat 410 which is mounted on the same rack as the magnet assembly 402.

The magnet assembly 402 includes a support assembly to allow alignment of the primary magnet relative to a sample region defined by a resonator unit inside the cryostat 410. The support assembly in the magnet assembly 402 may be implemented as the support assembly 122, 202, 302 as shown in FIGS. 1, 2A-2B, 3A-3J, or in another manner.

The sample handling unit 408 includes a sample tower and sightlines to allow the user to observe the sample mounting location and to ensure easy insertion. The sample handling unit 408 is configured to automatically load and unload a cartridge or a cassette of cartridges into the cryostat 410 without requiring user input. In some implementations, the sample handing unit 408 may be implemented as the sample handling unit 412 in FIG. 1 or in another manner.

The computer and signal processing units 406 include an integrated keyboard, a mouse, a touch screen monitor, and other input/output devices allowing for direct access to system controls and for displaying measurement process and results. Real-time experimental data is displayed, including dipolar oscillations in a distance measurement, rabi oscillations in a nutation measurement, field-dependent spin signal amplitudes in a spectrum measurement or another type of data in another type of experiment. In some implementations, the computer and signal processing units 406 may be implemented as the computer and signal processing units 102 in FIG. 1 or in another manner.

The cryostat 410 may be cooled by liquid Helium or liquid Nitrogen or by a closed cycle cooling system which does not require liquid cryogens, and can be maintained at a cryogenic environment (e.g., at 77 K, 4 K, or other cryogenic temperatures below 273 K). In some instances, the cryostat 410 of the example magnetic resonance system 400 includes internal control hardware for temperature setting and stabilization.

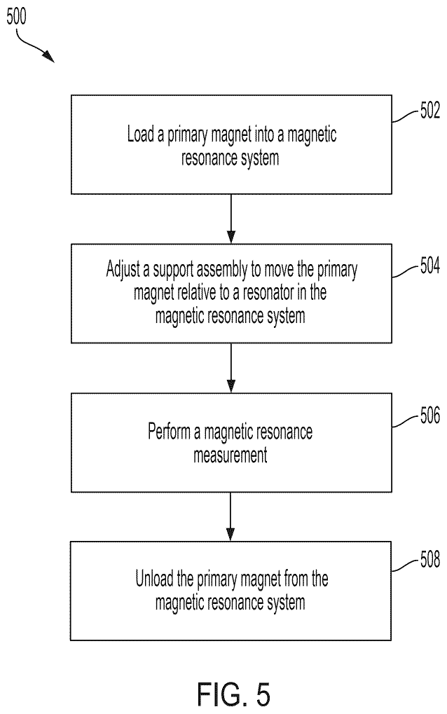

FIG. 5 is a flow chart showing aspects of an example process 500 for operating a support assembly of a magnetic resonance system. The example process 500 can be used to perform an iterative adjustment process to adjust a sample region relative to a primary magnetic field generated by a primary magnet. In some implementations, the example process 500 can include adjusting the support assembly 302 of the magnet assembly 300 as shown in FIGS. 3A-3J.

In some implementations, one or more adjustments in the example process 500 can be performed by an automated system. For instance, the magnetic resonance system may include a control system and one or more servo motors; the control system can specify adjustments to be made and control the servo motors to make the specified adjustments.

The servo motors can receive control signals that cause the servo motors to adjust actuators in the magnetic resonance system, thereby effectuating the adjustments. In some implementations, one or more adjustments in the example process 500 can be performed manually.

At 502, a primary magnet is loaded into a magnetic resonance system. In some instances, the primary magnet (e.g., the primary magnet 304) is supported on a mounting frame (e.g., the mounting frame 312 in FIGS. 3A-3J) in a support assembly (e.g., the support assembly 302 in FIGS. 3A-3J). The mounting frame can be loaded onto and securely held by a stage assembly (e.g., the stage assembly 306 in FIGS. 3A-3J) of the support assembly.

At 504, the support assembly is adjusted to move the primary magnet relative to the resonator unit. In some examples, the location and orientation of the primary magnet are adjusted to adjust the location and orientation of the sample region (e.g., the sample region 208) within the primary magnetic field (e.g., the primary magnetic field 210 in FIG. 2A-2B) generated by the primary magnet (e.g., the primary magnet 204 in FIGS. 2A-2B). In some instances, alignment of the primary magnet 204 relative to the sample region 208 can be measured by monitoring characteristics of a spin system of a standard sample in the sample region 208, for example, spectral shape or various decay times. A standard sample can be used for performing the alignment process. The standard sample can be placed in the magnetic resonance system at the sample region 208, for example, by operation of the sample handling unit 112 in FIG. 1. The orientation and location of the primary magnet 204 can be adjusted by operating the actuators 218, 220, the aligning pins 322A, 322B, the eccentric cam 324, and the linear actuators 323 of the support assembly 204, 302 in FIGS. 2A-2B, 3A-3 iteratively.

At 506, a magnetic resonance measurement is performed. In some aspects of operation, the example magnetic resonance system (e.g., the example magnetic resonance system 100, 200, 400 in FIGS. 1, 2A-2B, 4A-4C) operates in a normal mode of magnetic resonance measurement. For example, the magnetic resonance system may perform CW EPR or CW NMR spectroscopy measurements, pulsed ESR or pulsed NMR spectroscopy measurements, or other types of magnetic resonance experiments. In these modes of operation, magnetic resonance control signals are delivered to the resonator unit (e.g., the resonator unit 106), which causes the resonator unit to generate a magnetic resonance control field (e.g., a pulse or a CW field) that is applied to spins in a sample; a magnetic resonance detection signal is obtained (e.g., due to an interaction between the spins and the resonator unit) and processed in order to measure the spins'response to the magnetic resonance control field. In some instances, the example magnetic resonance system 100 includes electronic components for both CW and pulsed modes of operation, which allows the system to switch between these modes of operation without hardware modification or other intervention.

At 508, the primary magnet is unloaded from the magnetic resonance system. The primary magnet (e.g., the primary magnet 304) supported on the mounting frame 312 can be unloaded from the stage assembly 306 of the support assembly 302 onto a cart which allows access to and maintenance on the cryostat 410 or other components of the magnetic resonance system.

In a general aspect of what is described above, a primary magnetic field is adjusted in a magnetic resonance system.

In a first example, a magnetic resonance system includes a primary magnet configured to generate a primary magnetic field; a resonator that defines a sample region in the primary magnetic field; and a support assembly that supports the primary magnet. The support assembly includes a plurality of actuators configured to adjust the sample region in the primary magnetic field by moving the primary magnet relative to the resonator. The plurality of actuators are configured to adjust the sample region in at least five spatial degrees of freedom.

Implementations of the first example may include one or more of the following features. The plurality of actuators are configured to adjust the sample region in the primary magnetic field independently in three linear degrees of freedom; and two rotational degrees of freedom. The support assembly includes a mounting frame that holds the primary magnet; and a stage assembly that supports the mounting frame. The stage assembly includes a plate that contacts the mounting frame; locking clamps that secure the mounting frame to the plate; and a base that supports the plate. The plurality of actuators include a first subset on the stage assembly configured to move the mounting frame relative to the resonator. The plurality of actuators include a second subset on the mounting frame configured to move the primary magnet relative to the resonator.

Implementations of the first example may include one or more of the following features. The first subset includes a first pin configured to translate the mounting frame in a first direction; and a second pin configured to translate the mounting frame in a second direction. The first subset includes a cam configured to rotate the mounting frame about a first axis of rotation oriented in a third direction. The first, second and third directions are mutually orthogonal. The second subset includes screws configured to translate the primary magnet in a third direction and rotate the primary magnet about a second axis of rotation oriented in a fourth direction. The magnetic resonance system includes a cart configured to move the mounting frame relative to the stage assembly. The stage assembly includes rolling supports that support the mounting frame when the primary magnet is loaded onto, or unloaded from, the stage assembly. The primary magnet includes one of an electromagnet, a superconducting magnet, or a permanent magnet.

In a second example, a method of adjusting a magnetic resonance system includes adjusting a support assembly that supports a primary magnet. The primary magnet generates a primary magnetic field in a sample region defined by a resonator and adjusting the support assembly moves the primary magnet relative to the resonator. The support assembly includes a plurality of actuators that are configured to adjust a location of the sample region in the primary magnetic field in five degrees of freedom. Adjusting the support assembly includes adjusting at least one of the plurality of actuators.

Implementations of the second example may include one or more of the following features. Adjusting the sample region in the primary magnetic field includes independently adjusting three linear degrees of freedom; and two rotational degrees of freedom. The support assembly includes a mounting frame that holds the primary magnet; and a stage assembly that supports the mounting frame. The stage assembly includes a plate that contacts the mounting frame; locking clamps that secure the mounting frame to the plate; and a base that supports the plate.

Implementations of the second example may include one or more of the following features. The plurality of actuators include a first subset on the stage assembly, and adjusting the support assembly includes adjusting the first subset to move the mounting frame relative to the resonator. The plurality of actuators include a second subset on the mounting frame, and adjusting the support assembly includes adjusting the second subset to move the primary magnet relative to the resonator. The first subset includes a first pin and a second pin. Adjusting the first subset includes adjusting the first pin to translate the mounting frame in a first direction; and adjusting the second pin to translate the mounting frame in a second direction. The first subset includes a cam, and adjusting the first subset includes adjusting the cam to rotate the mounting frame about a first axis of rotation oriented in a third direction. The first, second and third directions are mutually orthogonal. The second subset includes screws, and adjusting the second subset includes adjusting the screws to translate the primary magnet in a third direction and rotate the primary magnet about a second axis of rotation oriented in a fourth direction. The magnetic resonance system includes a cart. The stage assembly includes rolling supports that support the mounting frame, and the method includes moving the mounting frame on the rolling supports relative to the stage assembly; and unloading the mounting frame from the stage assembly onto the cart. The primary magnet includes one of an electromagnet, a superconducting magnet, or a permanent magnet.

While this specification contains many details, these should not be understood as limitations on the scope of what may be claimed, but rather as descriptions of features specific to particular examples. Certain features that are described in this specification or shown in the drawings in the context of separate implementations can also be combined. Conversely, various features that are described or shown in the context of a single implementation can also be implemented in multiple embodiments separately or in any suitable subcombination.

Similarly, while operations are depicted in the drawings in a particular order, this should not be understood as requiring that such operations be performed in the particular order shown or in sequential order, or that all illustrated operations be performed, to achieve desirable results. In certain circumstances, multitasking and parallel processing may be advantageous. Moreover, the separation of various system components in the implementations described above should not be understood as requiring such separation in all implementations, and it should be understood that the described program components and systems can generally be integrated together in a single product or packaged into multiple products.

A number of examples have been described. Nevertheless, it will be understood that various modifications can be made. Accordingly, other examples are within the scope of the following claims.

1. A magnetic resonance system comprising:
a primary magnet configured to generate a primary magnetic field;
a resonator that defines a sample region in the primary magnetic field; and
a support assembly that supports the primary magnet, the support assembly comprising a plurality of actuators configured to adjust the sample region in the primary magnetic field by moving the primary magnet relative to the resonator, wherein the plurality of actuators are configured to adjust the sample region in at least five spatial degrees of freedom.

2. The magnetic resonance system of claim 1, wherein the support assembly comprises:
a mounting frame that holds the primary magnet; and
a stage assembly that supports the mounting frame.

3. The magnetic resonance system of claim 2, wherein the stage assembly comprises:
a plate that contacts the mounting frame;
locking clamps that secure the mounting frame to the plate; and
a base that supports the plate.

4. The magnetic resonance system of claim 2, wherein the plurality of actuators comprise a first subset of actuators on the stage assembly configured to move the mounting frame relative to the resonator.

5. The magnetic resonance system of claim 4, wherein the plurality of actuators comprise a second subset of actuators on the mounting frame configured to move the primary magnet relative to the resonator.

6. The magnetic resonance system of claim 5, wherein the first subset of actuators comprises:
a first pin configured to translate the mounting frame in a first direction; and
a second pin configured to translate the mounting frame in a second direction.

7. The magnetic resonance system of claim 6, wherein the first subset of actuators comprises a cam configured to rotate the mounting frame about a first axis of rotation oriented in a third direction.

8. The magnetic resonance system of claim 7, wherein the first, second and third directions are mutually orthogonal.

9. The magnetic resonance system of claim 7, wherein the second subset of actuators comprises screws configured to translate the primary magnet in a third direction and rotate the primary magnet about a second axis of rotation oriented in a fourth direction.

10. The magnetic resonance system of claim 2, comprising a cart configured to move the mounting frame relative to the stage assembly, wherein the stage assembly comprises rolling supports that support the mounting frame when the primary magnet is loaded onto, or unloaded from, the stage assembly.

11. The magnetic resonance system of claim 1, wherein the plurality of actuators are configured to adjust the sample region in the primary magnetic field independently in:
three linear degrees of freedom; and
two rotational degrees of freedom.

12. The magnetic resonance system of claim 1, wherein the primary magnet comprises one of:
an electromagnet;
a superconducting magnet; or a permanent magnet.

13. The magnetic resonance system of claim 1, wherein the plurality of actuators are configured to adjust:
a position of the sample region in three spatial degrees of freedom; and
an orientation of the sample region in two spatial degrees of freedom.

14. A method of adjusting a magnetic resonance system, the method comprising:
adjusting a support assembly that supports a primary magnet, wherein the primary magnet generates a primary magnetic field in a sample region defined by a resonator, and adjusting the support assembly moves the primary magnet relative to the resonator,
wherein the support assembly comprises a plurality of actuators that are configured to adjust the sample region in the primary magnetic field in five degrees of freedom, and adjusting the support assembly comprises adjusting at least one of the plurality of actuators.

15. The method of claim 14, wherein the support assembly comprises:
a mounting frame that holds the primary magnet; and
a stage assembly that supports the mounting frame.

16. The method of claim 15, wherein the stage assembly comprises:
a plate that contacts the mounting frame;
locking clamps that secure the mounting frame to the plate; and
a base that supports the plate.

17. The method of claim 15, wherein the plurality of actuators comprise a first subset of actuators on the stage assembly, and adjusting the support assembly comprises adjusting the first subset of actuators to move the mounting frame relative to the resonator.

18. The method of claim 17, wherein the plurality of actuators comprise a second subset of actuators on the mounting frame, and adjusting the support assembly comprises adjusting the second subset of actuators to move the primary magnet relative to the resonator.

19. The method of claim 18, wherein the first subset of actuators comprises a first pin and a second pin, and adjusting the first subset of actuators comprises:
adjusting the first pin to translate the mounting frame in a first direction; and
adjusting the second pin to translate the mounting frame in a second direction.

20. The method of claim 19, wherein the first subset of actuators comprises a cam, and adjusting the first subset of actuators comprises:
adjusting the cam to rotate the mounting frame about a first axis of rotation oriented in a third direction.

21. The method of claim 20, wherein the first, second and third directions are mutually orthogonal.

22. The method of claim 20, wherein the second subset comprises screws, and adjusting the second subset of actuators comprises:
adjusting the screws to translate the primary magnet in a third direction and rotate the primary magnet about a second axis of rotation oriented in a fourth direction.

23. The method of claim 15, wherein the magnetic resonance system comprises a cart, the stage assembly comprises rolling supports that support the mounting frame, and the method comprises:
moving the mounting frame on the rolling supports relative to the stage assembly; and
unloading the mounting frame from the stage assembly onto the cart.

24. The method of claim 14, wherein adjusting the sample region in the primary magnetic field comprises independently adjusting:
three linear degrees of freedom; and
two rotational degrees of freedom.

25. The method of claim 14, wherein the primary magnet comprises one of:
an electromagnet;
a superconducting magnet; or a permanent magnet.

26. The method of claim 14, wherein adjusting the support assembly rotates the primary magnet relative to the resonator.

27. The method of claim 14, wherein adjusting the support assembly translates the primary magnet relative to the resonator.

28. The method of claim 14, wherein adjusting the sample region in the primary magnetic field comprises adjusting:
a position of the sample region in three spatial degrees of freedom; and
an orientation of the sample region in two spatial degrees of freedom.
